(19) United States
(12) Patent Application Publication
(10) Pub. No.: US 2010/0112734 A1
(43) Pub. Date: May 6, 2010

(54) APPARATUS AND METHOD FOR MANUFACTURING LED DEVICE

(75) Inventors: Hiroshi Koizumi, Kanagawa-ken (JP); Tetsuro Komatsu, Kanagawa-ken (JP); Yukihiro Ikeya, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/611,553

(22) Filed: Nov. 3, 2009

(30) Foreign Application Priority Data
Nov. 5, 2008 (JP) 2008-284681
Oct. 27, 2009 (JP) 2009-246184

(51) Int. Cl. H01L 33/00; B23P 19/00

(52) U.S. Cl. 438/27; 29/729; 257/E33.056; 257/E33.061

(57) ABSTRACT

A method for manufacturing an LED device, includes: mounting an LED chip, which emits a first light, on a bottom surface of a recess formed in an upper surface of a package, pouring a resin liquid containing phosphor particles, which emits a second light upon incidence of the first light, into the recess, fixing the package to a package fixing plate of an apparatus of the LED device, precipitating the phosphor particles in the resin liquid with a centrifugal force applying to the package in a direction from the upper surface to the lower surface of the package by rotating a rotary member with a rotary driving unit, and curing the resin liquid.

### CROSS-REFERENCE TO RELATED APPLICATIONS

This application is based upon and claims the benefit of priority from the prior Japanese Patent Application No. 2008-284681, filed on Nov. 5, 2008 and the prior Japanese Patent Application No. 2009-246184, filed on Oct. 27, 2009; the entire contents of which are incorporated herein by reference.

### BACKGROUND OF THE INVENTION

1. Field of the Invention

This invention relates to an apparatus and a method for manufacturing an LED device.

2. Background Art

An LED device emitting white light typically includes an LED (light-emitting diode) chip emitting blue light and a phosphor absorbing blue light and emitting light of yellow color, which is complementary to blue. Thus, the blue light emitted from the LED chip and the yellow light emitted from the phosphor are emitted outside the LED device and mixed into white light (see, e.g., International Publication WO 2002/059982 (FIG. 1)).

One method for manufacturing such an LED device is as follows. A package with a recess formed in the upper surface is fabricated, and an LED chip is mounted on the bottom surface of the recess. Next, a resin liquid with phosphor particles dispersed in a transparent resin is poured into the recess. Subsequently, it is left standing for a certain period of time to spontaneously precipitate the phosphor particles in the resin liquid and deposit the phosphor particles in a layer so as to cover the bottom surface of the recess and the LED chip. Subsequently, by heating treatment, the resin liquid is heat-cured to form a resin member. Thus, the aforementioned LED device is manufactured.

However, in this conventional method for manufacturing an LED device, it takes a long period of time, such as approximately 10 hours, to spontaneously precipitate the phosphor particles, which decreases the productivity of the LED device. Furthermore, the resin liquid absorbs water and expands during the spontaneous precipitation. Then, during heat curing, the absorbed water is separated out at the interface with the package, and the resin liquid shrinks. Consequently, the resin member is delaminated from the package, which causes the problem of degradation in the quality of the LED device.

### SUMMARY OF THE INVENTION

According to an aspect of the invention, there is provided an apparatus for manufacturing an LED device, the LED device having a package with a recess formed in its upper surface, an LED chip mounted in the recess, a resin member filled in the recess, and phosphor particles precipitated in a lower portion of the resin member, the apparatus including: a base; a rotary member rotatably attached to the base and having a rotation axis extending vertically; and a holder coupled to the rotary member and supporting the package, an upper surface of the package being flexible to turn to the direction opposite to the resultant of gravity and the centrifugal force applying to the package.

According to another aspect of the invention, there is provided a method for manufacturing an LED device, including: mounting an LED chip on a bottom surface of a recess formed in an upper surface of a package, the LED chip emitting light of a first wavelength; pouring a resin liquid containing phosphor particles into the recess, the phosphor particle emitting light of a second wavelength longer than the first wavelength upon incidence of light of the first wavelength; precipitating the phosphor particles in the resin liquid by applying a centrifugal force to the package in a direction from the upper surface to a lower surface of the package; and curing the resin liquid.

### BRIEF DESCRIPTION OF THE DRAWINGS

FIG. 1 is a cross-sectional view illustrating an LED device manufactured in an embodiment of the invention;

FIG. 2 is a front view illustrating an apparatus for manufacturing the LED device according to the embodiment;

FIGS. 3A to 3C are process cross-sectional views illustrating a manufacturing method of the LED device according to the embodiment;

FIGS. 4A to 4C are process cross-sectional views illustrating a manufacturing method of the LED device according to the embodiment; and

FIG. 5 is a front view illustrating an apparatus for manufacturing an LED device according to a variation of the embodiment.

### DETAILED DESCRIPTION OF THE INVENTION

An embodiment of the invention will now be described with reference to the drawings.

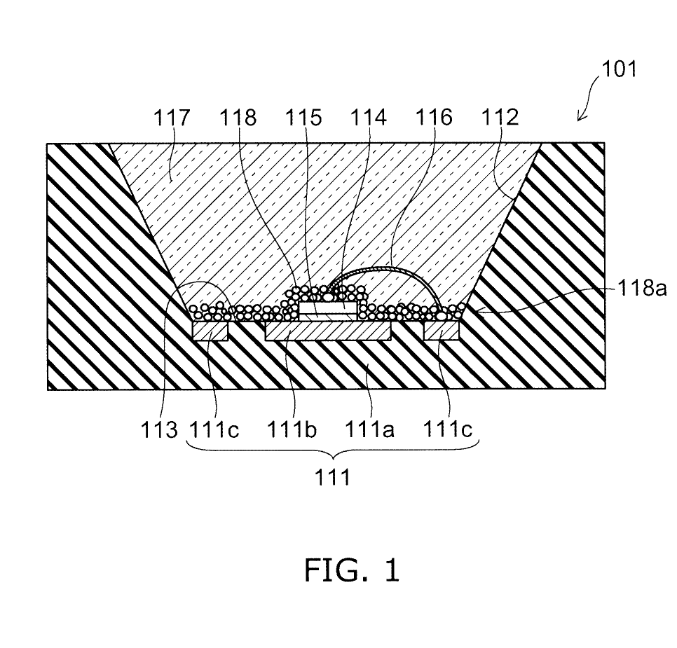

FIG. 1 is a cross-sectional view illustrating an LED device manufactured in this embodiment.

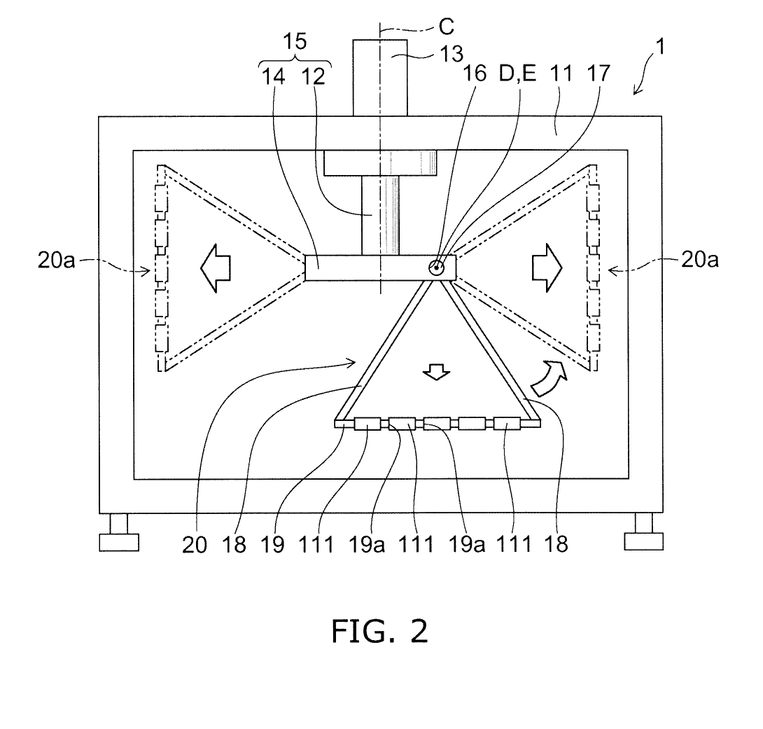

FIG. 2 is a front view illustrating an apparatus for manufacturing an LED device according to this embodiment.

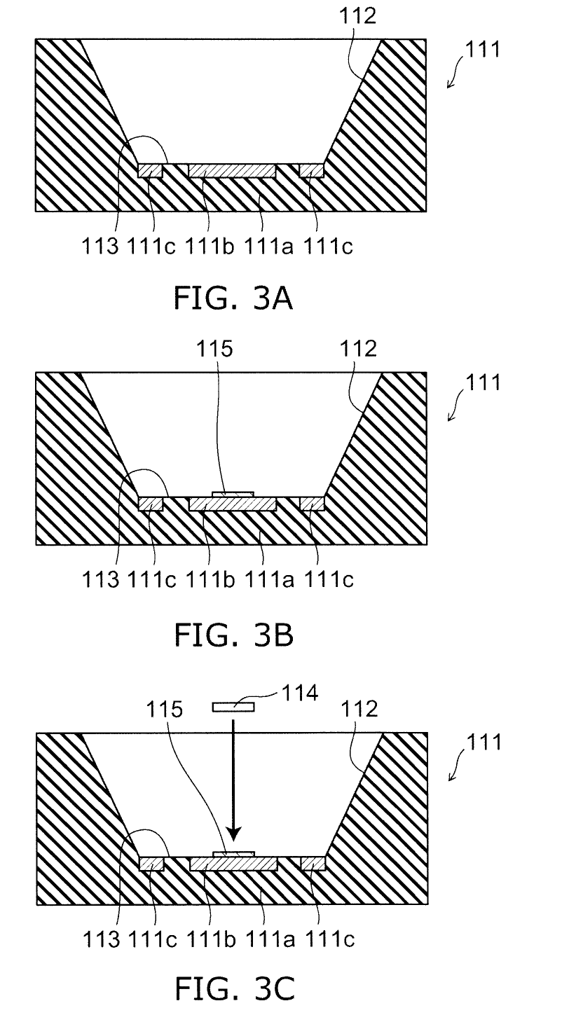

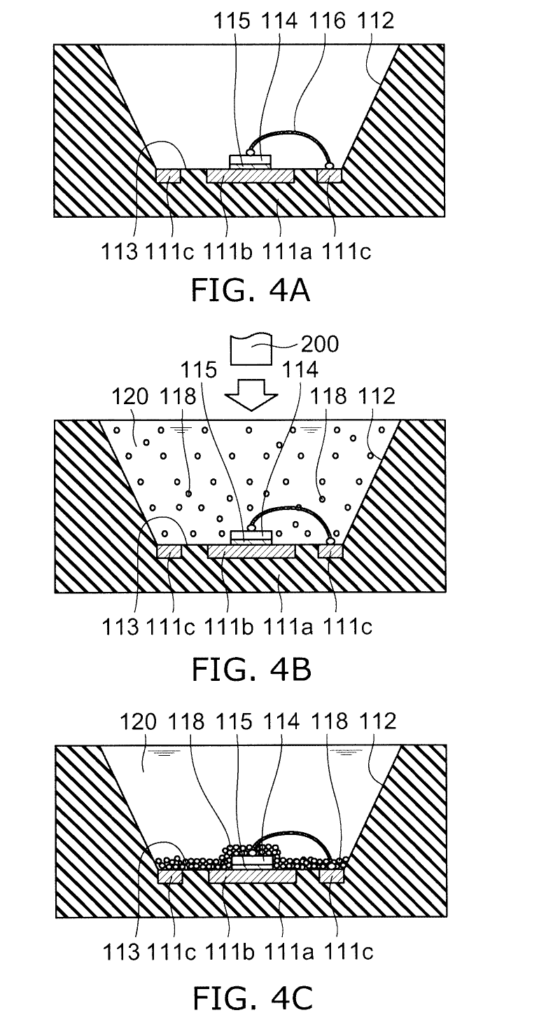

In FIG. 1, the phosphor particles are drawn schematically, larger than in reality. Furthermore, the solder layer 115 is drawn thicker than in reality. The same also applies to FIGS. 3 and 4 described later.

First, an LED device manufactured in this embodiment is described.

As shown in FIG. 1, an LED device 101 includes a package 111, and a recess 112 is formed in the upper surface of the package 111. The recess 112 is illustratively shaped like a funnel with the side surface beveled and opening upward. The package 111 is formed from a package body 111a made of an insulating material, such as a white ceramic or white resin, in which a negative electrode 111b and a positive electrode 111c are embedded. The negative electrode 111b and the positive electrode 111c are exposed to the bottom surface 113 of the recess 112.

An LED chip 114 is provided in the recess 112. The LED chip 114 is illustratively a light-emitting element, which emits blue light, and its shape is like a rectangular plate. The LED chip 114 is mounted at the center of the bottom surface 113 of the recess 112, and the lower surface of the LED chip 114 is connected to the negative electrode 111b through a solder layer 115. The upper surface of the LED chip 114 is connected to the positive electrode 111c through a wire 116.

A resin member 117 made of a transparent resin is filled in the recess 112. The resin member 117 is illustratively formed from silicone resin or epoxy resin. The depth of the recess 112 is larger than the thickness of the LED chip 114, and the LED chip 114 and the wire 116 are embedded in the resin member 117. Furthermore, numerous phosphor particles 118 are mixed in the resin member 117 and deposited in a layer in contact with the bottom surface 113 and with the upper surface and the side surface of the LED chip 114. Thus, a deposition layer 118a made of the phosphor particles 118 covers the LED chip 114. The phosphor particle 118 is formed from a fluorescent material, which is excited upon incidence of the blue light emitted from the LED chip 114 and emits light, such as yellow light, having a longer wavelength than the incident light. The fluorescent material can be a silicate material or silicon oxynitride material with an alkaline earth metal used as a host material, or one of these fluorescent materials activated with rare earth ions, excited primarily by visible light. The resin member 117 transmits the blue light emitted by the LED chip 114 and the yellow light emitted by the phosphor particle 118.

In such an LED device 101, upon energization by the negative electrode 111b and the positive electrode 111c, the LED chip 114 emits blue light in all directions. Of the emitted lights, the downward light is blocked by the package 111, but the upward and lateral light penetrate into the resin member 117. Part of the blue light penetrated into the resin member 117 is incident on and absorbed by the phosphor particles 118. Thus, the fluorescent material forming the phosphor particle 118 is excited and emits light, such as yellow light, having a longer wavelength than the incident light. This yellow light penetrates into the resin member 117. On the other hand, the rest of the blue light penetrated into the resin member 117 is not incident on the phosphor particles 118, but propagates in the resin member 117 as blue light. The yellow light and blue light propagated in the resin member 117 are emitted from the opening of the recess 112 to the outside of the recess 112 directly from the resin member 117 or after being reflected by the side surface of the recess 112, and thereby emitted outside the LED device 101. Here, the blue light emitted from the LED chip 114 and the yellow light emitted from the phosphor particles 118 are mixed, and hence the light emitted from the LED device 101 exhibits a white color.

Next, an apparatus for manufacturing an LED device according to this embodiment is described.

The apparatus for manufacturing an LED device according to this embodiment is an apparatus for manufacturing the LED device 101 shown in FIG. 1.

As shown in FIG. 2, the LED device manufacturing apparatus 1 (hereinafter also simply referred to as “apparatus 1”) according to this embodiment includes a base 11. The base 11 has such rigidity as not to move or significantly vibrate even during operation of the apparatus 1, and is illustratively fixed with respect to the installation position of the apparatus 1.

A rotary shaft member 12 is rotatably attached to the base 11. The rotary shaft member 12 is shaped like a cylinder and penetrates through the base 11, and its central axis extends in the vertical direction. Furthermore, the rotary shaft member 12 rotates with its central axis serving as a rotation axis C. Here, the “vertical direction” is the direction of gravity.

A rotary driving unit 13 for rotating the rotary shaft member 12 is provided on the base 11. The rotary driving unit 13 is illustratively a speed controlling motor. The rotary driving unit 13 is fixed to the base 11, and its rotary shaft is coupled to the upper end portion of the rotary shaft member 12 through a coupling (not shown). Furthermore, the apparatus 1 includes a controller (not shown) for controlling the rotary driving unit 13.

A rotary support member 14 is fixed to the lower end portion of the rotary shaft member 12. Hence, when the rotary shaft member 12 rotates, the rotary support member 14 rotates integrally therewith. The rotary support member 14 is a bar-shaped member extending in the horizontal direction. Here, the “horizontal direction” is a direction orthogonal to the vertical direction. The rotary shaft member 12 and the rotary support member 14 constitute a rotary member 15.

In the tip portion of the rotary support member 14, that is, at a position E displaced from the rotation axis C in the rotary member 15, a through hole 16 extending in a horizontal direction orthogonal to the direction from the rotation axis C to the position E is formed, and a pivot shaft member 17 is fitted in the through hole 16. The pivot shaft member 17 is shaped like a cylinder and pivotably attached to the rotary support member 14. That is, the through hole 16 and the pivot shaft member 17 constitute a bearing mechanism. The extending direction of the pivot axis D of the pivot shaft member 17 is the same as the extending direction of the through hole 16, hence extending in the horizontal direction orthogonal to the direction from the rotation axis C to the position E. The pivot shaft member 17 has a pivot angle of 90° or more, and is illustratively rotatable.

A pair of frames 18 is coupled to the pivot shaft member 17. The pair of frames 18 is arranged at a certain angle therebetween so that the frames 18 are spaced farther from each other with the distance from the pivot shaft member 17. A package fixing plate 19 is coupled between the tip portions of this pair of frames 18. The pair of frames 18 and the package fixing plate 19 constitute a holder 20. The holder 20 is suspended at the position E in the rotary member 15.

As viewed along the extending direction of the pivot axis D, the holder 20 is shaped like an isosceles triangle with the apex at the pivot axis D and the base at the package fixing plate 19. A plurality of containers 19a, each for containing the package 111 (see FIG. 1) of the LED device 101 described above, are formed on the major surface of the package fixing plate 19. Thus, the holder 20 can hold a plurality of packages 111. For instance, a plurality of containers 19a are arranged in a matrix on the package fixing plate 19.

By pivoting of the pivot shaft member 17 at a pivot angle of at least 90°, the direction from the position E to the container 19a of the package fixing plate 19 is pivotable between the vertical downward direction and the horizontal direction from the rotation axis C to the position E. Thus, the direction which the upper surface of the package turns to is flexible between the vertical upward direction and the horizontal direction to the rotation axis c. Consequently, the upper surface of the package 111 can change to turn to the direction opposite to the resultant of gravity and the centrifugal force applying to the package 111 when the rotary member 15 rotates.

Next, the operation of the LED device manufacturing apparatus according to this embodiment configured as above, that is, a method for manufacturing an LED device according to this embodiment, is described.

FIGS. 3A to 3C and 4A to 4C are process cross-sectional views illustrating the method for manufacturing an LED device according to this embodiment.

First, as shown in FIG. 3A, a package 111 is fabricated. As described above, in the package 111, a recess 112 is formed in the upper surface of the package body 111a, and a negative electrode 111b and a positive electrode 111c are embedded in the bottom surface 113 of the recess 112.

Next, as shown in FIG. 3B, a solder layer 115 is formed at the center of the bottom surface 113 of the recess 112. The solder layer 115 is connected to the negative electrode 111b.

Next, as shown in FIG. 3C, an LED chip 114 is bonded to the solder layer 115. Thus, the lower surface of the LED chip 114 is connected to the negative electrode 111b through the solder layer 115, and the LED chip 114 is mounted on the bottom surface 113.

Next, as shown in FIG. 4A, a wire 116 is bonded between the upper surface of the LED chip 114 and the positive electrode 111c. Thus, the upper surface of the LED chip 114 is connected to the positive electrode 111c through the wire 116.

Next, as shown in FIG. 4B, a resin liquid 120 is poured from a dispenser 200 into the recess 112. The resin liquid 120 is made of a transparent resin such as silicone resin or epoxy resin, and contains numerous phosphor particles 118. At this stage, the resin liquid 120 is in a liquid state, and the phosphor particles 118 are uniformly dispersed in the resin liquid 120. The phosphor particle 118 is solid.

Next, as shown in FIG. 2, with the rotary member 15 stopped, the package 111 is fixed to the container 19a of the package fixing plate 19 of the apparatus 1. Thus, the holder 20 holds the package 111. At this time, by the weight of the holder 20 and the package 111 held on the holder 20 (hereinafter collectively referred to as “package-mounting holder 20a”), the direction from the pivot axis D to the center of gravity of the package-mounting holder 20a is directed vertically downward. That is, the package-mounting holder 20a is suspended at the position E of the rotary member 15. Furthermore, because the holder 20 is shaped like an isosceles triangle as viewed along the extending direction of the pivot axis D, the major surface of the package fixing plate 19 is made horizontal, and the upper surface of the package 111 is also held horizontally. Thus, the resin liquid 120 poured into the recess 112 does not spill out.

Next, the controller (not shown) of the apparatus 1 is operated to drive the rotary driving unit 13. Thus, with the package 111 held on the holder 20, the rotary member 15 is rotated. As a result, besides gravity, a centrifugal force acts on the package-mounting holder 20a suspended at the position E displaced from the rotation axis C in the rotary member 15. Furthermore, the pivot shaft member 17 is pivotable with respect to the rotary member 15. Hence, the direction from the pivot axis D to the center of gravity of the package-mounting holder 20a is inclined in alignment with the direction of the resultant of gravity and the centrifugal force acting on the package-mounting holder 20a. In other words, the upper surface of the package 111 turns to the direction opposite to the resultant of gravity and the centrifugal force applying to the package 111.

Then, if the rotation speed of the rotary driving unit 13 is sufficiently increased, the centrifugal force becomes significantly larger than gravity, and the direction from the pivot axis D to the center of gravity of the package-mounting holder 20a is made nearly horizontal. Thus, the centrifugal force is applied to the package 111 in a direction from the upper surface to the lower surface of the package 111, and forcibly precipitates the phosphor particles 118 in the resin liquid 120. Also at this time, the resin liquid 120 does not spill out of the recess 112 because the force applied to the package 111 is directed from the upper surface to the lower surface of the package 111.

Then, the package-mounting holder 20a is rotated for a certain period of time. When the phosphor particles 118 in the resin liquid 120 are sufficiently precipitated, the rotary driving unit 13 is stopped. Thus, the centrifugal force ceases to act on the package-mounting holder 20a, and the direction from the position E to the center of gravity of the package-mounting holder 20a returns to the vertically downward direction. Subsequently, the package 111 is detached from the apparatus 1.

Thus, as shown in FIG. 4C, the phosphor particles 118 are precipitated in the resin liquid 120. Also at this stage, the resin liquid 120 remains in the liquid state. Because the pivot shaft member 17 is pivotable with respect to the rotary member throughout the above process of rotating the package-mounting holder 20a, the force acting on the package 111 is always directed from the upper surface to the lower surface of the package 111. Hence, the deposition layer of the phosphor particles 118 has a uniform thickness. Furthermore, the resin liquid 120 does not spill out of the recess 112 of the package 111.

Next, the package 111 is heated. For instance, in a thermostatic bath, the package 111 is maintained at a temperature of 150° C. for one hour. Thus, the resin liquid 120 is heat-cured into a resin member 117. Consequently, the LED device 101 shown in FIG. 1 is manufactured.

In the following, a numerical example of this embodiment is described.

The rotation radius of the package 111 in the apparatus 1, that is, the sum of the distance from the rotation axis C to the position E and the distance from the position E to the container 19a of the package fixing plate 19, is approximately 30 cm. The rotation speed of the rotary driving unit 13 is approximately 1000 rpm. In this case, a centrifugal force of approximately 335 G is applied to the package 111. Thus, precipitation of phosphor particles, which takes 10 hours in spontaneous precipitation, can be completed within one hour.

Next, the effect of this embodiment is described.

According to this embodiment, when the phosphor particles 118 in the resin liquid 120 are precipitated to form a deposition layer 118a covering the LED chip 114, by applying a centrifugal force to the package 111 with the apparatus 1, the time required for precipitation can significantly be reduced. For instance, in the above example, by application of a centrifugal force, precipitation is completed within one hour, although it takes 10 hours in spontaneous precipitation.

This significantly increases the productivity of the LED device 101. Furthermore, the amount of water absorbed by the resin liquid 120 during precipitation is small, and the volume expansion is small. Hence, the volume shrinkage in heat-curing the resin liquid 120 is also small, and the amount of water separated out between the resin liquid 120 and the side surface of the recess 112 is also small. This can prevent delamination of the resin member 117 from the recess 112. Furthermore, by application of a large centrifugal force to the phosphor particles 118, the thickness of the deposition layer 118a can be made uniform. Hence, light emission of the deposition layer 118a is made uniform. Thus, according to this embodiment, it is possible to efficiently manufacture an LED device with good quality.

Furthermore, a plurality of containers 19a are formed in the package fixing plate 19 of the apparatus 1. Hence, the precipitation treatment can be simultaneously performed on a plurality of packages 111. This can further increase the productivity of the LED device.

Next, a variation of this embodiment is described.

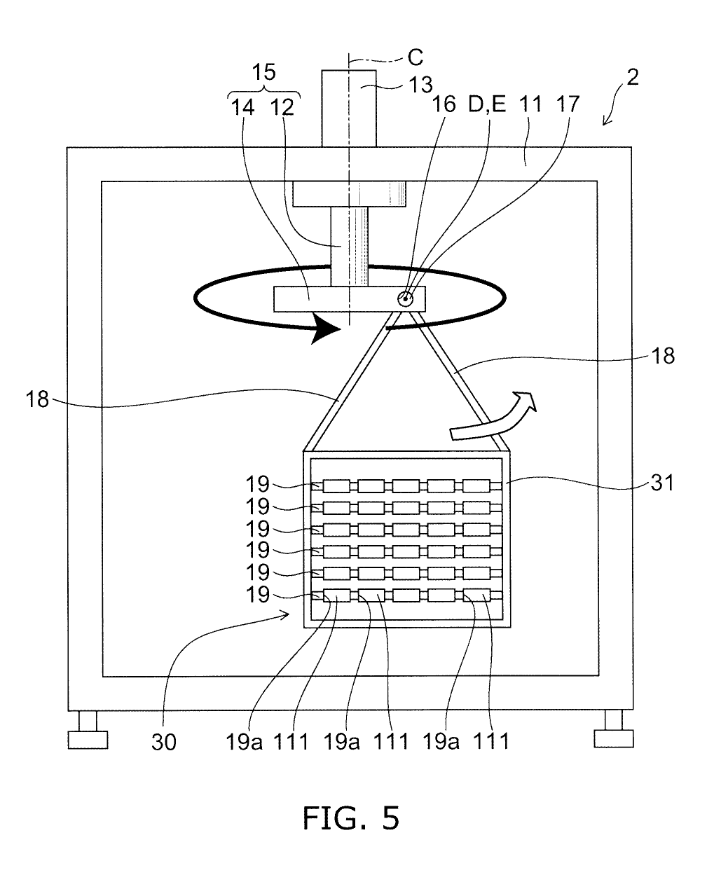

FIG. 5 is a front view illustrating an apparatus for manufacturing an LED device according to this variation.

As shown in FIG. 5, the LED device manufacturing apparatus 2 according to this variation is different from the apparatus 1 (see FIG. 2) according to the above embodiment in the configuration of the holder.

More specifically, like the holder 20 (see FIG. 2) of the apparatus 1, the holder 30 of the apparatus 2 includes a pair of frames 18 coupled to a pivot shaft member 17. However, the frames 18 do not directly hold a package fixing plate 19, but hold a package fixing plate 19 through a carrier 31. The carrier 31 holds a plurality of package fixing plates 19 arranged in multiple stages. For instance, each package fixing plate 19 is removable from the carrier 31. Furthermore, as in the above embodiment, each package fixing plate 19 includes a plurality of containers 19a formed in a matrix. The holder 30 is pivotably suspended at the position E of the rotary member 15 through the pivot shaft member 17.

According to this variation, more packages can be rotated at a time. The configuration of the apparatus 2 other than the foregoing, the method for manufacturing an LED device, and the configuration of the LED device manufactured in this variation are the same as those in the above embodiment.

The invention has been described with reference to the embodiment and its variation. However, the invention is not limited to these embodiment and variation. For instance, those skilled in the art can suitably modify the above embodiment and variation by addition, deletion, or design change of components, or by addition, omission, or condition change of processes, and such modifications are also encompassed within the scope of the invention as long as they fall within the spirit of the invention.

For instance, in the LED device manufacturing apparatus 1 according to the above embodiment, a plurality of containers 19a is formed in the package fixing plate 19 to simultaneously hold a plurality of packages 111. However, the invention is not limited thereto, but the package fixing plate 19 may hold only one package 111.

Alternatively, the apparatus 1 can include a plurality of holders 20 to hold more packages 111. In this case, to provide n holders 20 (n is an integer of two or more), these holders 20 are preferably placed at positions with n-fold symmetry about the rotation axis C. Then, even if the rotary member 15 is rotated, the center of gravity of the apparatus 1 does not change, and vibration of the apparatus 1 can be suppressed. For instance, in the case of providing two holders 20, they can be provided at both end portions of the rotary support member 14. In the case of providing three or more holders 20, the rotary support member 14 can be shaped like a disc instead of a bar, and the holders 20 can be placed equidistantly along the periphery of the disc. In this case, the holders 20 are placed so as to avoid interference with each other. Also in the apparatus 2 according to the above variation, a plurality of holders 30 can be provided.

Furthermore, in the above embodiment, the apparatus 1 illustratively includes a rotary driving unit 13. However, the invention is not limited thereto, but the rotary member 15 may be manually rotated.

Furthermore, in the above embodiment, the rotary shaft member 12 and the rotary support member 14 illustratively constitute the rotary member 15. However, the invention is not limited thereto, and the rotary member 15 may integrally be formed. Moreover, a through hole 16 may be formed in the tip of the overhang portion of the rotary member 15, and a pivot shaft member 17 may be fitted in the through hole 16.

Furthermore, the above embodiment illustratively indicates that the holder 20 is suspended at the position E in the rotary member 15 by the frames 18 and rocked by a centrifugal force. However, the invention is not limited thereto. It is sufficient that a holder supports the package 111, and the upper surface of the package 111 is flexible to turn to the direction opposite to the resultant of gravity and the centrifugal force applying to the package 111 when the rotary member 15 rotates. For instance, while the holder is fixed to the rotary member 15 and supports the package 111, the holder may be movable for the rotary member 15.

In specific, the holder may be fixed to the rotary member 15; the interior surface of the holder near the rotation axis c of the rotary member 15 may be horizontal but may continuously change to become vertical with the distance from the rotation axis c; and the package 111 may be able to move along the interior surface of the holder. For instance, the interior surface of the holder may be a hemispherical shape having a center in a point on the rotation axis c; a plurality of rails may be formed from the lowest part in a radial fashion; and the package 111 may be guided by the rails and become movable.

1. An apparatus for manufacturing an LED device, the LED device having a package with a recess formed in its upper surface, an LED chip mounted in the recess, a resin member filled in the recess, and phosphor particles precipitated in a lower portion of the resin member, the apparatus comprising:
a base;
a rotary member rotatably attached to the base and having a rotation axis extending vertically; and
a holder coupled to the rotary member and supporting the package,
an upper surface of the package being flexible to turn to the direction opposite to the resultant of gravity and the centrifugal force applying to the package.

2. The apparatus according to claim 1, wherein the holder is suspended at a position displaced from the rotation axis in the rotary member, and
the direction from the position displaced from the rotation axis to a portion of the holder holding the package is pivotable between a vertically downward direction and a horizontal direction from the rotation axis to the position.

3. The apparatus according to claim 2, further comprising:
a pivot shaft member pivotably attached to the rotary member at the position displaced from the rotation axis, having a pivot axis extending in a horizontal direction orthogonal to the direction from the rotation axis to the position, and coupled to the holder.

4. The apparatus according to claim 3, wherein a through hole is formed at the position displaced from the rotation axis in the rotary member, the pivot shaft member is fitted in the through hole, and the through hole and the pivot shaft member constitute a bearing mechanism.

5. The apparatus according to claim 2, wherein the rotary member includes:
a rotary shaft member rotatably attached to the base, shaped like a vertically extending cylinder, and rotating with its central axis serving as the rotation axis; and
a rotary support member fixed to the rotary shaft member, extending in a direction crossing the rotation axis, and having a tip portion at which the holder is suspended.

6. The apparatus according to claim 1, further comprising:
one or more other holders,
denoting by n the number of the holder and the other holders, where n is an integer of two or more, the holder and the other holders being placed at positions with n-fold symmetry about the rotation axis.

7. The apparatus according to claim 1, wherein the holder holds a plurality of the packages.

8. The apparatus according to claim 1, wherein the holder includes a package fixing plate in which a container for containing the package is formed on its major surface.

9. The apparatus according to claim 8, wherein the major surface of the package fixing plate is horizontal when the rotary member is stopped.

10. The apparatus according to claim 7, wherein the holder includes:
a plurality of package fixing plates each holding a plurality of the packages; and
a carrier holding the plurality of package fixing plates arranged in multiple stages.

11. The apparatus according to claim 10, wherein each of the package fixing plates is removable from the carrier.

12. The apparatus according to claim 1, further comprising:
a rotary driving unit configured to rotate the rotary member.

13. The apparatus according to claim 12, wherein the rotary driving unit is a speed controlling motor.

14. The apparatus according to claim 12, wherein the rotary driving unit is fixed to the base.

15. A method for manufacturing an LED device, comprising:
mounting an LED chip on a bottom surface of a recess formed in an upper surface of a package, the LED chip emitting light of a first wavelength;
pouring a resin liquid containing phosphor particles into the recess, the phosphor particle emitting light of a second wavelength longer than the first wavelength upon incidence of light of the first wavelength;
precipitating the phosphor particles in the resin liquid by applying a centrifugal force to the package in a direction from the upper surface to a lower surface of the package; and
curing the resin liquid.

16. The method according to claim 15, wherein the precipitating the phosphor particles is performed by using an apparatus, which includes a base, a rotary member rotatably attached to the base and having a rotation axis extending vertically, and a holder coupled to the rotary member and supporting the package, the upper surface of the package being flexible to turn to the direction opposite to the resultant of gravity and the centrifugal force applying to the package, to rotate the rotary member with the package supported by the holder.

17. The method according to claim 16, wherein the holder in the apparatus is suspended at a position displaced from the rotation axis in the rotary member, and the direction from the position displaced from the rotation axis to a portion of the holder holding the package is pivotable between a vertically downward direction and a horizontal direction from the rotation axis to the position.

18. The method according to claim 16, wherein the holder holds a plurality of the packages.

19. The method according to claim 16, wherein the precipitating the phosphor particles is performed by arranging a plurality of package fixing plates in multiple stages in the holder with a plurality of the packages held on each of the package fixing plates.

20. The method according to claim 15, wherein the curing the resin liquid includes heating the resin liquid.
